(19) United States
(12) Patent Application Publication
(10) Pub. No.: US 2022/0246875 A1
(43) Pub. Date: Aug. 4, 2022

(54) IMAGE SENSOR

(71) Applicant: ISORG, Limoges CEDEX 3 (FR)

(72) Inventors: Emeline SARACCO, GRENOBLE (FR); Benjamin BOUTHINON, GRENOBLE (FR); Tindara VERDUCI, GRENOBLE (FR); Elodie DESTOUESSE, GRENOBLE (FR); Jérémy LOUIS, GRENOBLE (FR)

(21) Appl. No.: 17/625,985

(22) PCT Filed: Jul. 9, 2020
(86) PCT No.: PCT/EP2020/069315

§ 371 Date: Jan. 10, 2022

(30) Foreign Application Priority Data
Jul. 16, 2019 (FR) 19/08017

(51) Int. Cl. H01L 51/44; H01L 27/30

(52) U.S. Cl. CPC H01L 51/448; H01L 51/4213; H01L 27/307

(57) ABSTRACT

A method of manufacturing an optoelectronic device that includes an optical sensor with organic photodiodes capable of capturing a radiation, the optical sensor covering an electronic circuit with MOS transistors. The method includes forming, on the optical sensor, on the side of the optical sensor opposite to the electronic device, a first layer transparent to the radiation, the first layer having a planar surface on the side opposite to the optical sensor; and forming a second layer on the surface, the second layer being oxygen- and water-tight.

The present patent application claims the priority benefit of French patent application FR19/08017 which is herein incorporated by reference.

### FIELD

The present disclosure generally concerns optoelectronic components based on optical sensors comprising organic photodiodes integrated on a substrate comprising MOS transistors.

### BACKGROUND

Many techniques of integration of optical sensors under a transparent screen are known, for example, for the integration of a fingerprint sensor in a cell phone or for the integration of optical sensors in a cell phone screen for facial recognition.

Certain sensors are integrated on substrates comprising MOS transistors forming the control electronics of the photodiodes.

### SUMMARY

One embodiment addresses all or some of the drawbacks of known optoelectronic devices.

An embodiment provides a method of manufacturing an optoelectronic device comprising an optical sensor with organic photodiodes capable of capturing a radiation, the optical sensor covering an electronic circuit with MOS transistors, the method comprising the successive steps of:

a) forming, on the optical sensor, on the side of the optical sensor opposite to the electronic circuit, a first layer transparent to said radiation, the first layer having a planar surface on the side opposite to the optical sensor; and
b) forming a second layer on said surface, the second layer being oxygen- and water-tight.

According to an embodiment, the electronic circuit comprises at its surface at least one electrically-conductive pad, the method further comprising the step of:

c) forming at least one first opening in the first layer to expose said pad.

According to an embodiment, the forming of the first opening is achieved by reactive ion etching.

According to an embodiment, the forming of the first opening is achieved by laser ablation.

According to an embodiment, the forming of the first opening is achieved by nanoimprint lithography.

According to an embodiment, the first layer is made of a material photosensitive to electromagnetic radiation and the forming of the first opening comprises a step of exposure of the first layer to said electromagnetic radiation.

According to an embodiment, step b) comes before step c), the method comprising, between steps b) and c), the step of forming a second opening in the second layer, the first opening being formed at step c) in line with the second opening.

According to an embodiment, the method further comprises the steps of:

forming a resist block facing said electrically-conductive pad, said block comprising a top and sides;
carrying out step c), where the second layer particularly covers the top of said block and does not totally cover the sides; and
removing said block.

According to an embodiment, step c) comes before step b), the second layer further covering the lateral walls of the first opening.

According to an embodiment, the first layer is made of a material selected from the group comprising polystyrene, polyepoxides, polyacrylates, organic resins, particularly resists, silicon nitride, and silicon dioxide.

According to an embodiment, the first layer is deposited by:

liquid deposition;
cathode sputtering;
physical vapor deposition;
thin-film deposition; or
plasma-enhanced chemical vapor deposition.

According to an embodiment, the first layer has an average thickness in the range from 100 nm to 15 μm, preferably from 500 nm to 5 μm, more preferably from 1 μm to 3 μm.

According to an embodiment, the second layer is made of a material selected from the group comprising aluminum oxide, silicon nitride, and silicon dioxide.

According to an embodiment, the second layer has an average thickness in the range from 2 nm to 300 nm.

According to an embodiment, the method further comprises the steps of:

forming a third antireflection and/or infrared-filtering layer; and
forming an array of microlenses.

An embodiment also provides an optoelectronic device comprising:

an electronic device with MOS transistors;
an optical sensor with organic photodiodes capable of capturing a radiation, the optical sensor covering the electronic circuit;
a first layer covering the optical sensor, on the side of the optical sensor opposite to the electronic circuit, the first layer being transparent to said radiation and having a planar surface on the side opposite to the optical sensor; and
a second planar layer on the first layer.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view of the structure obtained at a step of an embodiment of a method of manufacturing an optoelectronic device comprising organic photodiodes on an integrated circuit with MOS transistors;

FIG. 2 illustrates another step of the method;

FIG. 3 illustrates another step of the method;

FIG. 4 illustrates another step of the method;

FIG. 5 illustrates another step of the method;

FIG. 6 illustrates another step of the method;

FIG. 7 illustrates another step of the method;

FIG. 8 illustrates another step of the method;

FIG. 9 illustrates another step of the method;

FIG. 10 illustrates another step of the method;

FIG. 11 illustrates another step of the method;

FIG. 12 illustrates another step of the method;

FIG. 13 illustrates another step of the method;

FIG. 14 is a partial simplified cross-section view of the structure obtained at a step of another embodiment of a method of manufacturing an optoelectronic device comprising organic photodiodes on an integrated circuit with MOS transistors;

FIG. 15 illustrates another step of the method;

FIG. 16 illustrates another step of the method;

FIG. 17 illustrates another step of the method;

FIG. 18 illustrates another step of the method;

FIG. 19 is a partial simplified cross-section view of the structure obtained at a step of another embodiment of a method of manufacturing an optoelectronic device comprising organic photodiodes on an integrated circuit with MOS transistors;

FIG. 20 illustrates another step of the method;

FIG. 21 illustrates another step of the method;

FIG. 22 illustrates another step of the method;

FIG. 23 is a partial simplified cross-section view of the structure obtained at a step of another embodiment of a method of manufacturing an optoelectronic device comprising organic photodiodes on an integrated circuit with MOS transistors;

FIG. 24 illustrates another step of the method;

FIG. 25 illustrates another step of the method;

FIG. 26 illustrates another step of the method;

FIG. 27 is a partial simplified transverse cross-section view of an embodiment of a system comprising the optoelectronic device; and

FIG. 28 is a partial simplified transverse cross-section view of another embodiment of a system comprising the optoelectronic device.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In particular, the steps of forming the organic photodiodes and the underlying MOS transistors are not detailed.

Further, it is here considered that the terms “insulating” and “conductive” respectively mean “electrically insulating” and “electrically conductive”. The expression “active area” of a photodiode designates the area of the photodiode where most of the radiation of interest is captured by the photodiode. The expression “radiation of interest” designates the radiation which is desired to be captured by an optical sensor comprising photodiodes. As an example, the radiation of interest may comprise the visible spectrum and near infrared, that is, wavelengths in the range from 400 nm to 1,100 nm. The transmittance of a layer to a radiation corresponds to the ratio of the intensity of the radiation coming out of the layer to the intensity of the radiation entering the layer, the rays of the incoming radiation being perpendicular to the layer. In the following description, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%. In the following description, a film or a layer is said to be oxygen-tight when the permeability of the film or of the layer to oxygen at 40° C. is smaller than 1·10⁻¹ cm³/(m²*day). The permeability to oxygen may be measured according to the ASTM D3985 method entitled “Standard Test Method for Oxygen Gas Transmission Rate Through Plastic Film and Sheeting Using a Coulometric Sensor”. In the following description, a film or a layer is said to be water-tight when the permeability of the film or of the layer to water at 40° C. is smaller than 1·10⁻¹ g/(m²*day). The permeability to water may be measured according to the ASTM F1249 method entitled “Standard Test Method for Water Vapor Transmission Rate Through Plastic Film and Sheeting Using a Modulated Infrared Sensor”.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures. Unless specified otherwise, the expressions “around”, “approximately”, “substantially” and “in the order of” signify within 10%, and preferably within 5%.

FIGS. 1 to 13 are partial simplified cross-section views of structures obtained at successive steps of an embodiment of a method of manufacturing an optoelectronic device comprising a sensor with organic photodiodes and MOS transistors.

FIG. 1 is a partial simplified cross-section view of an example of an integrated circuit 101 comprising an array of MOS transistors 102, six MOS transistors 102 being schematically shown by rectangles in the drawings. According to an embodiment, integrated circuit 101 is formed by techniques conventional in microelectronics. Conductive pads are formed at the surface of integrated circuit 101. Among the conductive pads, pads 106 formed in an area 105 of integrated circuit 101 and which will be used as lower electrodes for organic photodiodes and, outside of area 105, for example, at the periphery of circuit 101, pads 108 which will be used for the biasing of the upper electrode of the photodiodes, a single pad 108 being shown in the drawings, and pads 109 which will be used for the biasing of integrated circuit 101, a single pad 109 being shown in the drawings, can be distinguished.

Conventionally, integrated circuit 101 may comprise a semiconductor substrate, for example, made of single-crystal silicon, having the insulated-gate field-effect transistors, also called MOS transistors, for example, N-type and P-type MOS transistors, formed inside and on top thereof, and a stack of insulating layers covering the substrate and transistors 102, conductive tracks and vias being formed in the stack to electrically couple transistors 102 and pads 106, 108, 109. Integrated circuit 101 may have a thickness in the range from 100 μm to 775 μm, preferably from 200 μm to 400 μm.

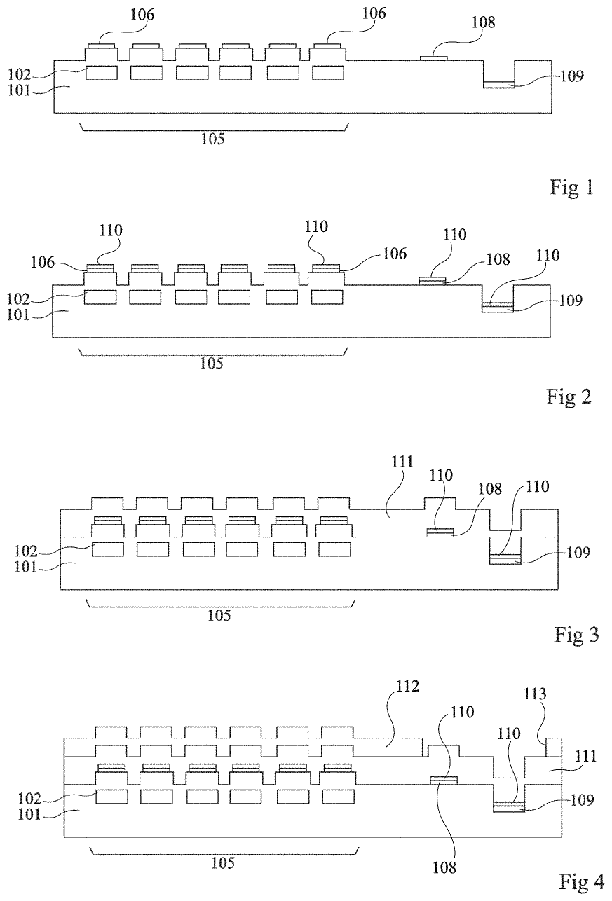

FIG. 2 shows the structure obtained after the forming on each pad 106 of an organic interface layer 110. The forming method used may further cause the forming of organic layer 110 on pads 108 and 109. Interface layer 110 may be made of cesium carbonate (CsCO₃), of metal oxide, particularly of zinc oxide (ZnO), or of a mixture of at least two of these compounds. Interface layer 110 may comprise a self-assembled monomolecular layer or a polymer, for example, (polyethyleneimine, ethoxylated polyethyleneimine, poly[(9,9-bis(3′-(N,N-dimethylamino)propyl)-2,7-fluorene)-alt-2,7-(9,9-dioctylfluorene)]. The thickness of interface layer 110 is preferably in the range from 0.1 nm to 1 μm. Interface layer 110 may graft in privileged fashion on pads 106 (and possibly 108 and 109), which directly provides the structure shown in FIG. 2. As a variant, interface layer 110 may be deposited over the entire structure shown in FIG. 1, and then be etched outside of pads 106, 108, 109 to provide the result illustrated in FIG. 2. According to another variant, not illustrated, interface layer 110 may be deposited over the entire structure shown in FIG. 1, this layer having a very low lateral conductivity so that it is not necessary to remove it outside of pads 106.

FIG. 3 shows the structure obtained after the forming of an organic layer 111, called active layer, over the entire structure shown in FIG. 2 and where, in operation, the active areas of the photodiodes will be formed. Active layer 111 may comprise small molecules, oligomers, or polymers. These may be organic or inorganic materials. Active layer 111 may comprise an ambipolar semiconductor material, or a mixture of an N-type semiconductor material and of a P-type semiconductor material, for example in the form of stacked layers or of an intimate mixture at a nanometer scale to form a bulk heterojunction. The thickness of active layer 111 may be in the range from 50 nm to 2 μm, for example, in the order of 300 nm.

Example of P-type semiconductor polymers capable of forming active layer 40 are poly(3-hexylthiophene) (P3HT), poly[N-9′-heptadecanyl-2,7-carbazole-alt-5,5-(4,7-di-2-thienyl-2′,1′,3′-benzothiadiazole)] (PCDTBT), poly[(4,8-bis-(2-ethylhexyloxy)-benzo[1,2-b;4,5-b′] dithiophene)-2,6-diyl-alt-(4-(2-ethylhexanoyl)-thieno[3,4-b] thiophene))-2,6-diyl] (PBDTTT-C), poly[2-methoxy-5-(2-ethyl-hexyloxy)-1,4-phenylene-vinylene] (MEH-PPV), or poly[2,6-(4,4-bis-(2-ethylhexyl)-4H-cyclopenta [2,1-b;3,4-b′]dithiophene)-alt-4,7(2,1,3-benzothiadiazole)] (PCPDTBT).

Examples of N-type semiconductor materials capable of forming active layer 112 are fullerenes, particularly C60, [6,6]-phenyl-C₆₁-methyl butanoate ([60]PCBM), [6,6]-phenyl-C₇₁-methyl butanoate ([70]PCBM), perylene diimide, zinc oxide (ZnO), or nanocrystals enabling to form quantum dots.

FIG. 4 shows the structure obtained after the deposition of a photosensitive resist layer 112 on active area 111, and the forming of openings 113 in photosensitive layer 112, by photolithography techniques, a single opening 113 being shown in FIG. 4, to expose organic layer 111 above pads 108 and 109.

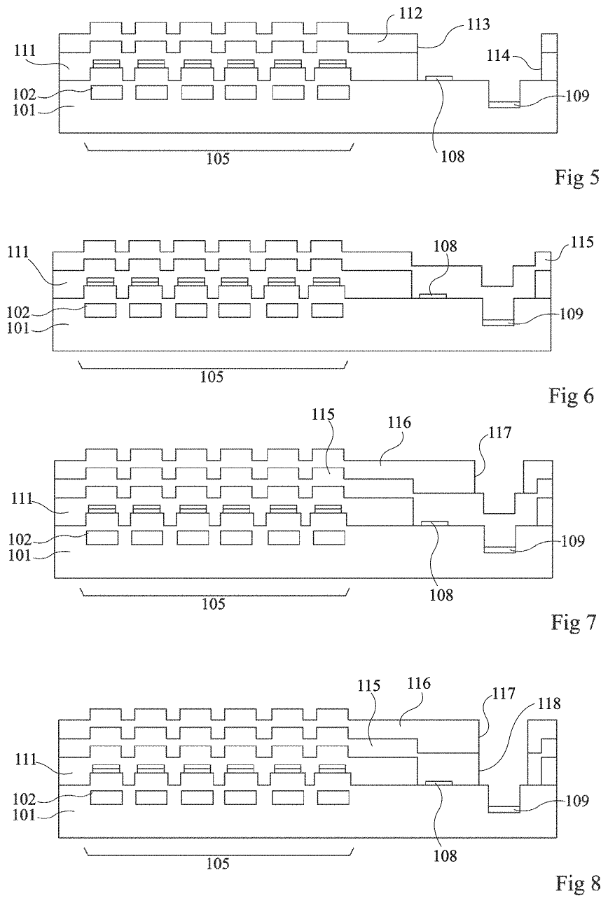

FIG. 5 shows the structure obtained after the etching of openings 114 in organic layer 111 in line with openings 113 of photosensitive layer 112, and the etching of layers 106 to expose pads 108 and 109.

FIG. 6 shows the structure obtained after the removal of photosensitive layer 112 and after the deposition, over the entire structure, of an electrode layer 115. Electrode layer 115 is particularly in contact with pads 108.

Electrode layer 115 is at least partially transparent to the light radiation captured by active layer 111. Electrode layer 115 may be made of a transparent conductive material, for example, of transparent conductive oxide or TCO, of carbon nanotubes, of graphene, of a conductive polymer, of a metal, or of a mixture or an alloy of at least two of these compounds. Conductive layer 115 may have a monolayer or multilayer structure.

Examples of TCOs capable of forming electrode layer 115 are indium tin oxide (ITO), aluminum zinc oxide (AZO), and gallium zinc oxide (GZO). Examples of conductive polymers capable of forming conductive layer 114 are polyaniline, also called PAni, and the polymer known as PEDOT:PSS, which is a mixture of poly(3,4)-ethylenedioxythiophene and of sodium poly(styrene sulfonate). Examples of metals capable of forming electrode layer 115 are silver (Ag), aluminum (Al), gold (Au), copper (Cu), nickel (Ni), titanium (Ti), and chromium (Cr). An example of a multilayer structure capable of forming electrode layer 115 is a multilayer AZO and silver structure of AZO/Ag/AZO type. Preferably, electrode layer 115 is made of PEDOT:PSS.

The thickness of oxide layer 115 may be in the range from 10 nm to 5 μm, for example, in the order of 30 nm. In the case where electrode layer 115 is metallic, the thickness of electrode layer 115 is smaller than or equal to 20 nm, preferably smaller than or equal to 10 nm.

FIG. 7 shows the structure obtained after the deposition of a photosensitive resist layer 116 on electrode layer 115, and the forming of openings 117 in photosensitive layer 116, by photolithography techniques, a single opening 117 being shown in FIG. 7, to expose electrode layer 115 above pads 109.

FIG. 8 shows the structure obtained after the etching of openings 118 in electrode layer 115 in line with the openings 117 of photosensitive layer 116 to expose pads 109.

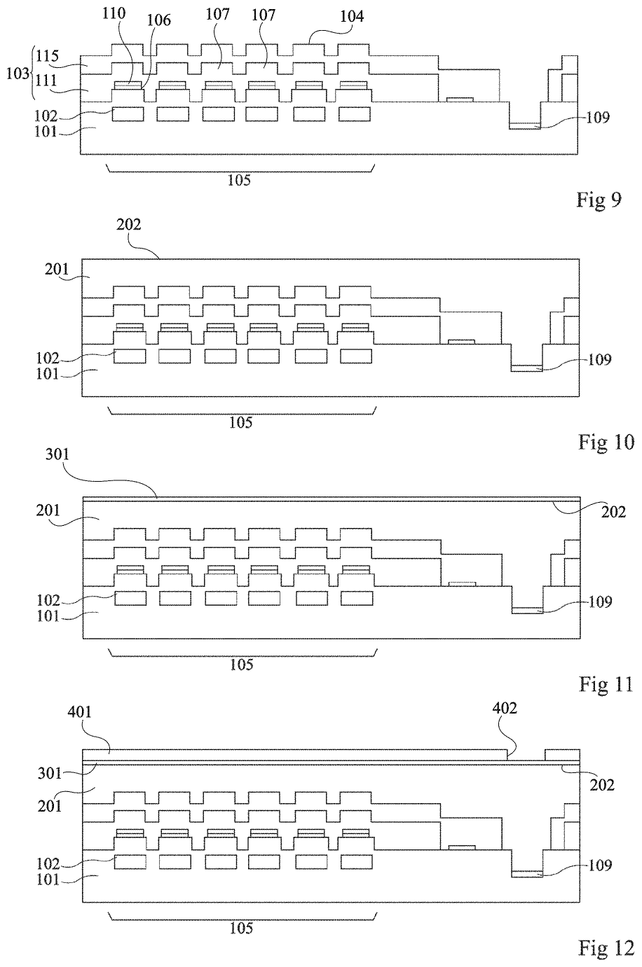

FIG. 9 shows the structure obtained after the removal of photosensitive layer 116. The stack 103 of organic layers 110, 111, 115 comprises an upper surface 104. The structure comprises, in area 105, an array of organic photodiodes 107 forming an optical sensor, each photodiode 107 being defined by the portion of organic layers 111, 115 facing one of electrodes 106. In the example of FIG. 9, six organic photodiodes 107 are shown. In practice, this array is located vertically in line with the array of transistors 102 which, in operation, may be used for the control and the reading out of photodiodes 107. In the present embodiment, layer 110 is shown as being discontinuous at the level of photodiodes 107 while organic layers 111 and 115 are shown as being continuous at the level of photodiodes 107. As a variant, interface layer 110 may be continuous at the level of photodiodes 107. As a variant, organic layers 111, 115 may be discontinuous at the level of photodiodes 107. Preferably, at least active layer 111 and electrode layer 115 are continuous at least at the level of photodiodes 107. This enables to avoid a step of etching the layers of stack 103 to define photodiodes 107. The thickness of the stack may be in the range from 300 nm to 1 μm, preferably from 300 nm to 500 nm.

According to an embodiment, the layers of stack 103 forming organic photodiodes 107 may be formed according to a so-called additive process, for example, by direct printing of a fluid or viscous composition comprising the material forming each layer at the desired locations, for example, by inkjet printing, heliography, silk-screening, flexography, spray coating, or drop-casting. The method of forming the organic layers may correspond to a so-called subtractive method, where the material forming the layers is deposited all over the structure and where the non-used portions are then removed, for example, by photolithography or laser ablation. According to the considered material, the deposition over the entire structure may be performed, for example, by liquid deposition, by cathode sputtering, or by evaporation. Methods such as spin coating, spray coating, heliography, slot-die coating, blade coating, flexography, or silk-screening, may in particular be used.

Electronic circuit 101 may have an upper surface comprising raised areas. This results in the forming of level differences in stack 103 having its layers following the shape of electronic circuit 101, and thus in the forming of raised areas on the upper surface 104 of stack 103. Upper surface 104 is accordingly not planar.

In a usual method of manufacturing an optoelectronic device based on optical sensors comprising organic photodiodes, it is necessary to cover stack 103 of organic layers with a protection layer, also called encapsulation layer. The encapsulation layer is substantially tight to water and to the oxygen of air to protect the organic layers of stack 103. The encapsulation layer may be made of an inorganic material, for example, of aluminum oxide (Al₂O₃), of silicon oxide (SiO₂), or of silicon nitride (Si₃N₄). The encapsulation layer may have a thickness varying from a few nanometers, for example, 2 nm, particularly when the encapsulation layer is formed by atomic layer deposition (ALD), to a thickness of approximately 200 nm, for example, when the encapsulation layer is formed by physical vapor deposition (PVD) or by plasma-enhanced chemical vapor deposition (PECVD), or even up to a thickness in the order of 10 μm, particularly when the encapsulation layer comprises a stack of organic and inorganic layers, where the inorganic layers may be made of the materials previously mentioned for the encapsulation layer and the organic layers may be made of epoxy resin, of acrylate resin, of parylene, or of rubber.

The presence of raised areas on surface 104 makes it difficult to form a homogeneous deposition to form the encapsulation layer. The desired tightness properties of the encapsulation layer may then locally not be obtained. Further, the method of manufacturing the encapsulation layer may be incompatible with the organic nature of the layers of stack 103. As an example, the electrode layer 115 at the top of stack 103 may be made of PEDOT:PSS, which is a hydrophilic material, and the forming of the Al₂O₃ encapsulation layer by ALD may use water vapor as a precursor. There will thus be an interaction of the PEDOT:PSS with the water vapor on forming of the encapsulation layer. This may cause the appearing of mechanical stress in stack 103, which may result in a partial separation of stack 103 from electronic circuit 101.

FIG. 10 shows the structure obtained after the forming of an intermediate layer 201, also called buffer layer, transparent to the radiation of interest, on the structure shown in FIG. 9. According to an embodiment, buffer layer 201 is self-planarizing, that is forms a substantially planar upper surface 202 under the action of gravity only. According to an embodiment, buffer layer 201 is obtained by the deposition of a liquid material on the structure shown in FIG. 9, so that substantially planar upper layer 202 is automatically obtained under the action of gravity. Buffer layer 201 can then be obtained by drying of the liquid material and/or by polymerization of the liquid material. Preferably, the deposited quantity of liquid material is such that the obtained buffer layer 201 covers all the raised areas present on surface 104 of stack 103.

According to an embodiment, buffer layer 201 is a dielectric, organic, or inorganic layer. Examples of organic materials are polystyrene, polyepoxides, polyacrylates, or organic resins, particularly resists. In particular, the viscosity and the thickness of the deposited material are adjusted to obtain the planarization of the encapsulation layer. Examples of inorganic materials are Si₃N₄ and SiO₂. In the case where buffer layer 201 is made of Si₃N₄ or of SiO₂, its deposition is for example performed by cathode sputtering, by PVD, or by PECVD.

According to another embodiment, in the case where the encapsulation layer forming method does not enable to automatically obtain substantially planar surface 202, the method may comprise a step of planarization of buffer layer 201. According to an embodiment, the planarization step may be performed by chemical-mechanical polishing (CMP).

The average thickness of buffer layer 201 is in the range from 100 nm to 15 μm, preferably from 500 nm to 5 μm, preferably from 1 μm to 3 μm.

FIG. 11 shows the structure obtained after a step of forming an encapsulation layer 301 on surface 202 of buffer layer 201. According to an embodiment, encapsulation layer 301 is water- and oxygen-tight. Preferably, buffer layer 201 also provides a protection for the organic layers of stack 103 against water and oxygen. Encapsulation layer 301 being formed on surface 202, which is substantially planar, this enables to form encapsulation layer 301 with a substantially constant thickness, which enables to ensure that the properties of encapsulation layer 301, particularly the tightness, are substantially homogeneous. Further, the material forming buffer layer 201 is advantageously selected to be compatible with the method implemented for the forming of encapsulation layer 301.

Encapsulation layer 301 is for example:

an aluminum oxide layer (Al₂O₃), for example obtained by ALD;

a Si₃N₄ or SiO₂ layer, for example obtained by PVD or by PECVD; or

a layer of a water- and oxygen-tight polymer, for example, polyethylene terephthalate (PET), polyethylene naphthalate (PEN), or cyclic olefin copolymers (COP).

According to an embodiment, encapsulation layer 301 has a thickness in the range from 2 nm to 300 nm, preferably from 2 nm to 200 nm, more preferably from 2 nm to 150 nm.

FIG. 12 shows the structure obtained after the deposition of a resist layer 401 on encapsulation layer 301 and the forming of openings 402 in resist layer 401, by photolithography techniques, to expose encapsulation layer 301 at the level of pads 109, a single opening 402 being shown in FIG. 12.

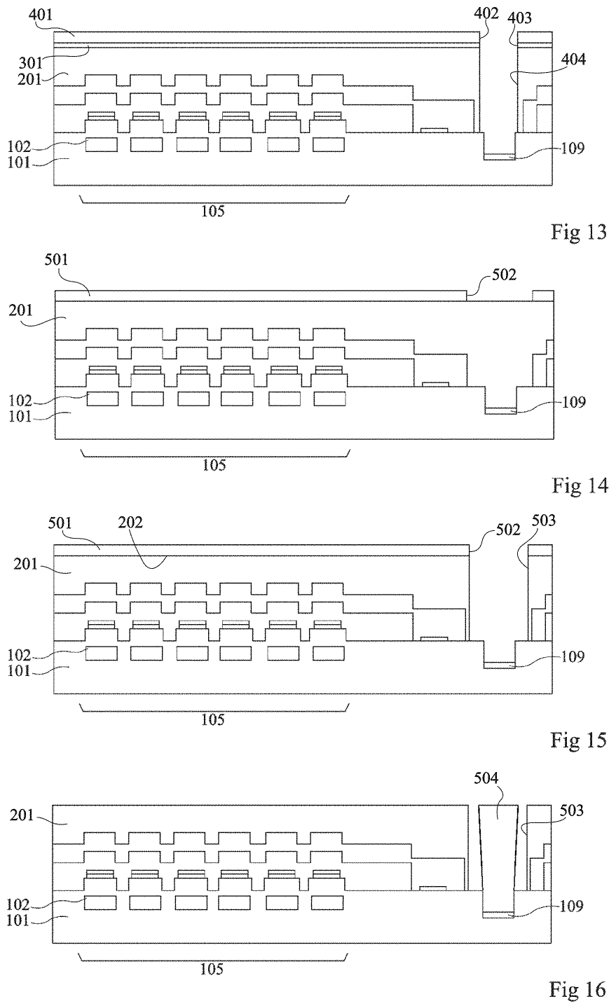

FIG. 13 shows the structure obtained after the etching of openings 403 in encapsulation layer 301 by using resist layer 401 as an etch mask, openings 403 being in line with openings 404 in buffer layer 201 across the entire thickness of buffer layer 201 by using encapsulation layer 301 as an etch mask, openings 404 being in line with openings 402, to expose pads 109. Openings 403 may be formed by wet etching. Openings 404 may be formed by reactive ion etching (RIE). The RIE may be performed with a gaseous mixture of oxygen and of sulfur hexafluoride (O₂+SF₆), a mixture of oxygen and of methane (O₂+CH₄), or pure oxygen (O₂). According to another embodiment, openings 403 are obtained by laser ablation of encapsulation layer 301. In this case, photosensitive layer 401 may be omitted. According to an embodiment, openings 404 are obtained by laser ablation of buffer layer 201.

According to an embodiment, openings 402, 403, 404, seen along a direction perpendicular to surface 202, have a surface area substantially greater than that of pads 109. For example, openings 402, 403, 404, seen along a direction perpendicular to surface 202, have dimensions in the order of 100 μm*100 μm while pads 109 have dimensions in the order of 70 μm*70 μm.

Even if the lateral walls of openings 404 are not covered with encapsulation layer 301, benefit is however taken from the water- and oxygen-tightness properties of buffer layer 201. Further, pads 109 and openings 404 may be located sufficiently far from photodiode array 107 for the degradation of the organic layers of stack 103 at the level of photodiodes 107 due to water and/or to oxygen to be decreased.

Openings 404 may be filled with a metallic material to enable to connect the optoelectronic device to an external element.

FIGS. 14 to 18 are partial simplified cross-section views of structures obtained at successive steps of another embodiment of a method of manufacturing an optoelectronic circuit comprising a sensor with organic photodiodes and MOS transistors.

FIG. 14 shows the structure obtained after the implementation of the steps previously described in relation with FIGS. 2 to 10, and after the deposition of a resist layer 501 on buffer layer 201 and the forming of openings 502 in photosensitive layer 501, by photolithography techniques, to expose buffer layer 201 at the level of pads 109, a single opening 502 being shown in FIG. 14. Photosensitive layer 501 may have the same composition and the same thickness as the previously-described photosensitive layer 401.

FIG. 15 shows the structure obtained after the etching of openings 503 in buffer layer 201 by using photosensitive layer 501 as an etch mask, openings 503 being in line with openings 502, to expose pads 109. Openings 503 may be formed by RIE. The RIE may be performed with a gaseous mixture of oxygen and of sulfur hexafluoride (O₂+SF₆), a mixture of oxygen and of methane (O₂+CH₄), or pure oxygen (O₂). According to an embodiment, openings 503 are obtained by laser ablation of buffer layer 201.

According to an embodiment, openings 503, seen along a direction perpendicular to surface 202, have a surface area substantially greater than that of pads 109. As an example, openings 503, seen along a direction perpendicular to the surface 202, have dimensions in the order of 100 μm*100 μm while pads 109 have dimensions in the order of 70 μm*70 μm.

FIG. 16 shows the structure obtained after a step of removal of photosensitive layer 501 and after a step of forming of a sacrificial block 504 on each pad 109. Each sacrificial block 504 is preferably made of resist. Sacrificial blocks 504 may be formed by photolithography steps. According to an embodiment, as shown in FIG. 16, each sacrificial block 504 may have a flared shape from the pad 109 on which it rests, or a so-called cap-shaped profile, that is, have a top of larger dimensions than the base in contact with pad 109. According to an example, such a shape may be particularly obtained by providing, during the photolithography steps, a step of hardening the surface of the photosensitive layer used to form blocks 504, for example, by dipping the resin layer into an aromatic solvent, such as chlorobenzene. According to another example, such a shape may be obtained during the resin layer development step, the resin being selected to have a development rate which varies along the direction perpendicular to the resin layer, the resin layer being more resistant to development on the side of its free upper surface. According to an embodiment, the dimensions of the base of block 504 are greater than those of pad 109 to ensure that block 504 covers the entire pad 109.

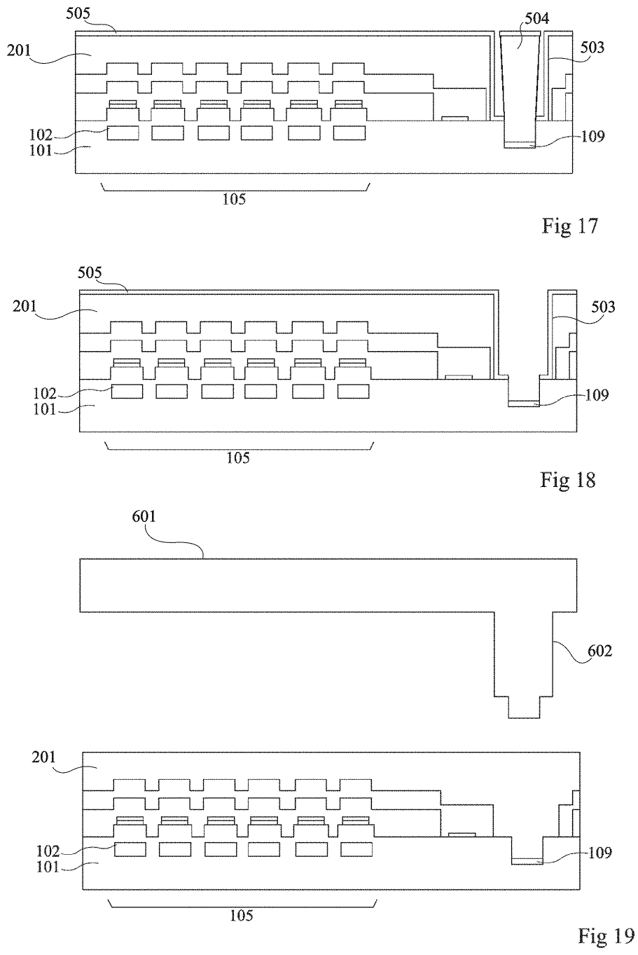

FIG. 17 shows the structure obtained after a step of deposition of an encapsulation layer 505 on the structure shown in FIG. 16. Encapsulation layer 505 has the same thickness and the same composition as the structure shown in FIG. 16. Encapsulation layer 505 has the same thickness and the same composition as the previously-described encapsulation layer 301 and may be formed by the same methods as those described previously for encapsulation layer 301. Encapsulation layer 505 extends on buffer layer 201, on the lateral walls and the bottom of openings 503, and on the upper surface of each sacrificial block 504. The method of forming encapsulation layer 505 is preferably a directional deposition method so that, due to the flared shape of block 504, which is wider at its top than at its base, encapsulation layer 505 does not deposit on at least part of the lateral walls of block 504. However, even with a deposition method known to be conformal, for example ALD, the encapsulation layer may not deposit on at least part of the lateral walls of block 504, particularly when the cap-shaped profile of block 504 is marked and the thickness of the encapsulation layer is very small, for example, smaller than 25 nm.

FIG. 18 shows the structure obtained after a step of removal of sacrificial blocks 505. According to an embodiment, this is performed by dipping of structure shown in FIG. 17 into a bath containing a solvent which dissolves sacrificial blocks 505.

The present embodiment of the method of forming the optoelectronic device has the advantage that the lateral walls of openings 503 are covered with encapsulation layer 505. The protection of organic photodiodes 107 against water and oxygen is thus increased.

Openings 503 may be filled with a metallic material to enable to connect the optoelectronic device to an external element.

FIGS. 19 to 22 are partial simplified cross-section views of structures obtained at successive steps of another embodiment of a method of manufacturing an optoelectronic circuit comprising a sensor with organic photodiodes and MOS transistors.

FIG. 19 shows the structure obtained after the implementation of the steps previously described in relation with FIGS. 2 to 10. FIG. 19 further shows a punch 601 comprising micrometer-scale raised patterns 602, a single pattern 602 being shown in FIG. 19, patterns 602 substantially having shapes complementary to the openings which are desired to be formed in buffer layer 201.

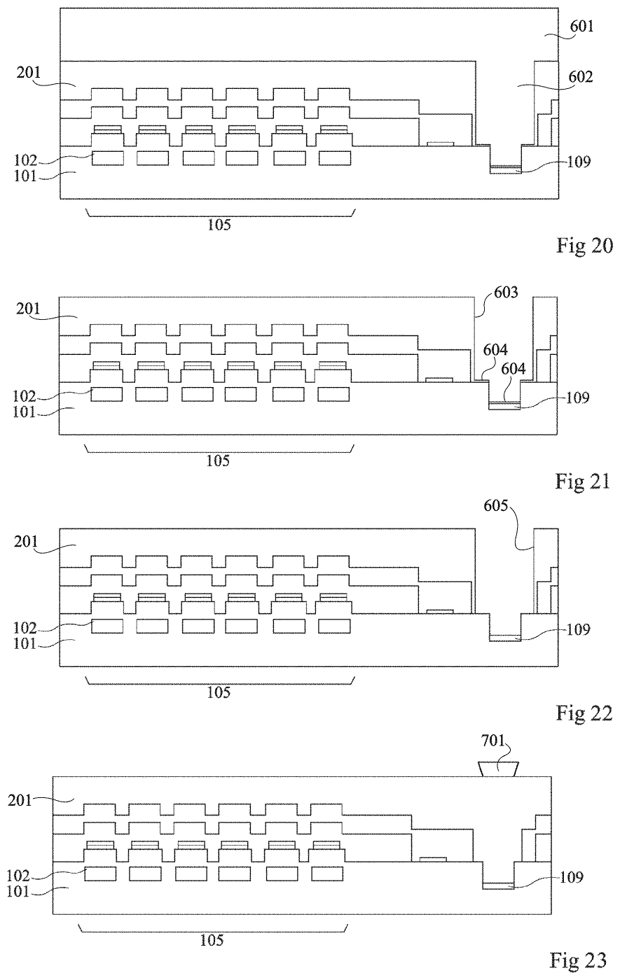

FIG. 20 shows the structure obtained after a step of nanoimprint lithography (NIL) comprising the application of punch 601 against buffer layer 201 so that patterns 602 penetrate into buffer layer 201. According to an embodiment, the application of punch 601 against buffer layer 201 is performed under pressure. According to an embodiment, the application of a punch 601 against buffer layer 201 is performed at a temperature higher than the vitreous transition temperature of the material forming buffer layer 201.

FIG. 21 shows the structure obtained after the removal of punch 601. Recesses 603 substantially having the shape of the desired openings are present in buffer layer 201. Undesirable residues 604 of buffer layer 201 may be present, particularly on pads 109 and the rest of optoelectronic circuit 101.

FIG. 22 shows the structure obtained after a step of directional etching, for example, of plasma etching, to remove residues 604. The desired openings 605 exposing pads 109 are thus obtained.

The present method carries on with the deposition of an encapsulation layer, not shown, over the entire structure and particularly in openings 605 and on pads 109 and the removal, for example, by etching, of the portion of the encapsulation layer to expose pads 109, or by the forming of sacrificial resin blocks on pads 109, by the deposition of the encapsulation layer over the entire structure and by the removal of the sacrificial blocks, for example as previously described in relation with FIGS. 16 to 18.

The present embodiment enables to form openings 605 in buffer layer 201 without using a mask having its openings defined by photolithography steps. This may be advantageous, particularly when buffer layer 201 is thick, since the layer of resist deposited on buffer layer 201 for a use as a mask should generally have a thickness greater than that of buffer layer 201.

FIGS. 23 to 26 are partial simplified cross-section views of structures obtained at successive steps of another embodiment of a method of manufacturing an optoelectronic circuit comprising a sensor with organic photodiodes and MOS transistors.

FIG. 23 shows the structure obtained after the implementation of the steps previously described in relation with FIGS. 2 to 10, and after a step of forming of a sacrificial block 701 on buffer layer 201 substantially facing each pad 109. Each sacrificial block 701 is preferably made of resist. Sacrificial blocks 701 may be formed by photolithography steps. According to an embodiment, as shown in FIG. 23, each sacrificial block 701 may have a flared shape as the distance to photosensitive layer 201 increases or a so-called cap-shaped profile, as previously described for blocks 504.

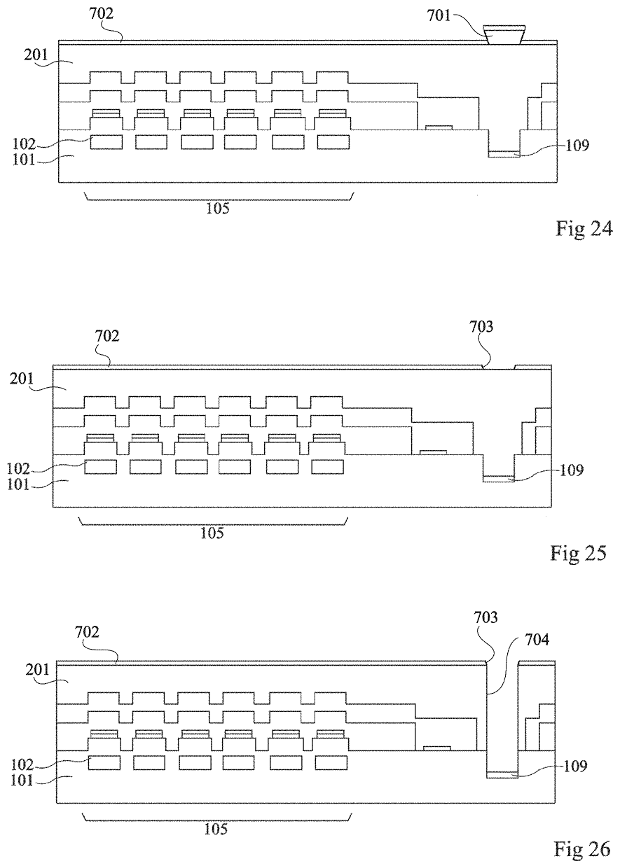

FIG. 24 shows the structure obtained after a step of deposition of an encapsulation layer 702 on the structure shown in FIG. 23. According to an embodiment, encapsulation layer 702 has the same thickness and the same composition as the previously-described encapsulation layer 301 and may be formed by the same methods as those previously described for encapsulation layer 301.

Encapsulation layer 702 extends on buffer layer 201 and on the upper surface of each sacrificial block 701. The method of forming encapsulation layer 702 is a directional deposition method so that, due to the flared shape of block 701, which is wider at its top than at its base, encapsulation layer 702 does not deposit over at least part of the lateral walls of block 701.

FIG. 25 shows the structure obtained after a step of removal of sacrificial blocks 701. According to an embodiment, this is achieved by dipping the structure shown in FIG. 24 into a bath containing a solvent which dissolves sacrificial blocks 701. As a variant, sacrificial blocks 701 may be removed by an isotropic RIE step. Openings 703 are thus defined in encapsulation layer 702 at the locations formerly occupied by sacrificial blocks 701, a single opening 703 being shown in FIG. 25.

FIG. 26 shows the structure obtained after the etching of openings 704 in buffer layer 201 by using encapsulation layer 201 as an etch mask, openings 704 being in line with openings 703, to expose pads 109. Openings 704 may be formed by RIE. The RIE may be performed with a gaseous mixture of oxygen and of sulfur hexafluoride (O₂+SF₆), a mixture of oxygen and of methane (O₂+CH₄), or pure oxygen (O₂).

Even if the lateral walls of openings 704 are not covered with encapsulation layer 702, benefit is however taken from the water- and oxygen-tightness properties of buffer layer 201. Further, pads 109 and openings 704 may be located sufficiently far from photodiode array 107 for the degradation of the organic layers of stack 103 at the level of photodiodes 107 due to water and/or to oxygen to be decreased.

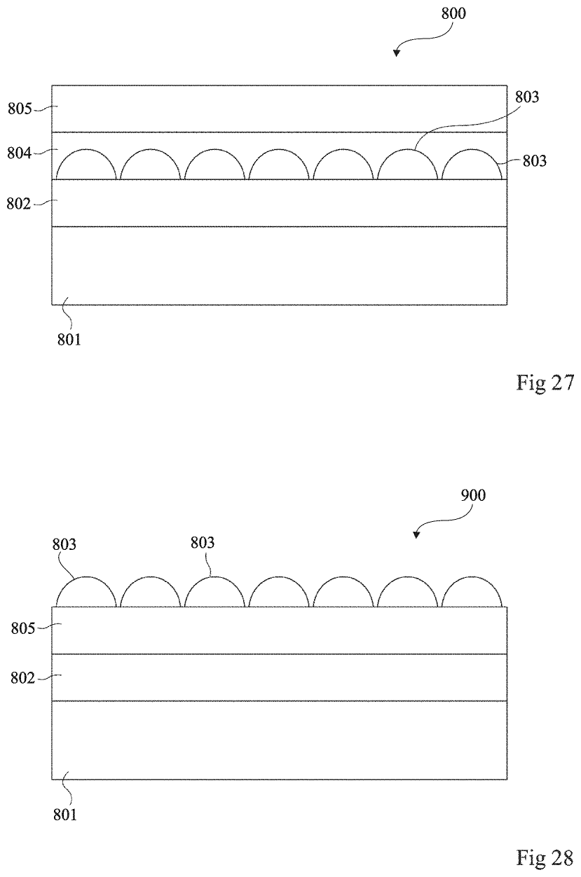

FIG. 27 is a partial simplified transverse cross-section view of an embodiment of a system 800 comprising an optoelectronic device 801 manufactured according to one of the previously-described embodiments of manufacturing methods.

System 800 further comprises, on optoelectronic device 801, from bottom to top in FIG. 27:

a planar transparent layer 802;
an array of microlenses 803;
a layer 804 having a low refraction index, layer 804 being possibly omitted; and
an antireflection and/or infrared-filtering coating 805.

Layer 802, arranged on optoelectronic device 801, may have the same composition as the previously-described buffer layer 201 and may be formed by the same methods. Layer 802 may have a thickness in the range from 100 nm to 15 μm, preferably from 1 μm to 3 μm.

Microlens array 803 may be deposited on layer 802 so that each microlens 803 faces a photodiode (not shown). Microlenses 803 have a thickness in the range from 0.4 μm to 10 μm, preferably from 0.4 μm to 2 μm, and a diameter in the range from 0.9 μm to 15 μm, preferably from 0.9 μm to 3 μm. Microlenses 803 may be made of poly(methyl) methacrylate (PMMA), of PET, of PEN, of COP, of polydimethylsiloxane (PDMS)/silicone, or of epoxy resin. Microlenses 803 advantageously enable to increase the collection of rays of the incident radiation towards photodiodes 107.

Layer 804 is deposited on microlens array 803. Layer 804 is for example made of a material comprising silicon oxide particles (SiO₂), an acrylic polymer, and epoxy resin as a binder. Layer 804 may have a thickness in the range from 0.4 μm to 10 μm, preferably from 0.4 μm to 3 μm.

According to an embodiment, coating 805 is formed by deposition, preferably of silicon oxynitride (SiOₓN_{y}), on layer 804 or directly on microlens array 803. Coating 805 may have a thickness in the range from 50 nm to 1 μm, preferably from 100 nm to 250 nm.

FIG. 28 is a partial simplified transverse cross-section view of another embodiment of a system 900 comprising an optoelectronic device 801 manufactured according to one of the previously-described embodiments of manufacturing methods.

System 900 comprises all the elements of previously-described system 800, with the difference that layer 804 is not present and that coating 805 is interposed between optoelectronic device 801 and transparent layer 802.

The embodiment of FIG. 27 or 28 is preferably implemented when the total thickness of transparent layer 201 and of encapsulation layer 501, 505, or 702 is greater than the spacing, or not, between each photodiode, for example, in the order of from 1 μm to 10 μm, preferably from 1 μm to 3 μm, for example, approximately 1.1 μm. This enables to focus the radiation towards each photodiode and thus avoid parasitic excitations of the neighboring photodiodes.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional indications provided hereinabove. In particular, in the steps of the embodiments previously described in relation with FIGS. 10 to 13 and 14 and 15, the etching of openings 404 or 503 in encapsulation layer 201 implements the deposition of a resist layer 401, 501 on encapsulation layer 201 and the forming of openings 402, 502 in resist layer 401, 501 by photolithography steps. According to another embodiment, in the case where encapsulation layer 201 is made of a material photosensitive to radiation, openings 404, 503 may be formed directly in the encapsulation layer by photolithography steps comprising exposing portions of the photosensitive encapsulation layer to the radiation.

1. A method of manufacturing an optoelectronic device comprising an optical sensor with organic photodiodes capable of capturing a radiation, the optical sensor covering an electronic circuit with MOS transistors, the method comprising the steps of:
a) forming, on the optical sensor, on the side of the optical sensor opposite to the electronic circuit, a first layer transparent to said radiation, the first layer having a planar surface on the side opposite to the optical sensor; and
b) forming a second layer on said surface, the second layer being oxygen- and water-tight,
wherein the electronic circuit comprises at its surface at least one electrically-conductive pad; and
c) forming at least a first opening in the first layer to expose said pad.

2. The method according to claim 1, further comprising the step of:
d) forming at least a second opening in the second layer facing said pad.

3. The method according to claim 1, wherein the forming of the first opening is achieved by reactive ion etching.

4. The method according to claim 1, wherein the forming of the first opening is achieved by laser ablation.

5. The method according to claim 1, wherein the forming of the first opening is achieved by nanoimprint lithography.

6. The method according to claim 1, wherein the first layer is made of a material photosensitive to electromagnetic radiation, and wherein the forming of the first opening comprises exposing the first layer to said electromagnetic radiation.

7. The method according to claim 1, wherein step b) comes before step c), the method further comprising, between steps b) and c), the step of forming a second opening in the second layer, the first opening being formed at step c) in line with the second opening.

8. The method according to claim 1, further comprising the steps of:
forming a resist block facing said electrically-conductive pad, said block comprising a top and sides;
carrying out step c), where the second layer covers the top of said block and does not totally cover the sides; and
removing said block.

9. The method according to claim 8, wherein step c) comes before step b), the second layer further covering the lateral walls of the first opening.

10. The method according to claim 1, wherein the first layer is made of a material selected from the group comprising polystyrene, polyepoxides, polyacrylates, organic resins, particularly resists, silicon nitride (Si₃N₄), and silicon dioxide (SiO₂).

11. The method according to claim 1, wherein the first layer is deposited by:
liquid deposition;
cathode sputtering;
physical vapor deposition;
thin-film deposition; or
plasma-enhanced chemical vapor deposition.

12. The method according to claim 1, wherein the first layer has an average thickness in the range from 100 nm to 15 μm.

13. The method according to claim 1, wherein the second layer is made of a material selected from the group comprising aluminum oxide (Al₂O₃), silicon nitride (Si₃N₄), and silicon dioxide (SiO₂).

14. The method according to claim 1, wherein the second layer has an average thickness in the range from 2 nm to 300 nm.

15. The method according to claim 1, further comprising the steps of:
forming a third antireflection and/or infrared-filtering layer; and
forming an array of microlenses.

16. An optoelectronic device comprising:
an electronic circuit with MOS transistors;
an optical sensor comprising organic photodiodes for capturing a radiation, the optical sensor covering the electronic circuit;
a first layer covering the optical sensor, on the side of the optical sensor opposite to the electronic circuit, the first layer transparent to said radiation and having a planar surface on the side opposite to the optical sensor; and
a second planar layer on the first layer.

17. The method according to claim 1, wherein the first layer has an average thickness in the range from 500 nm to 5 μm.

18. The method according to claim 1, wherein the first layer has an average thickness in the range from 1 μm to 3 μm.
